(19) United States
(12) Patent Application Publication
(10) Pub. No.: US 2023/0213593 A1
(43) Pub. Date: Jul. 6, 2023

(54) SUPERCAPACITOR TO ELECTROCHEMICAL HYBRID SYSTEM WITH SUPERCAPACITOR TESTING CAPABILITY

(71) Applicant: SUSTAINABLE ENERGY TECHNOLOGIES, INC., WILMINGTON, DE (US)

(72) Inventor: John Cronin, WILMINGTON, DE (US)

(21) Appl. No.: 18/091,822

(22) Filed: Dec. 30, 2022

Related U.S. Application Data
(60) Provisional application No. 63/295,427, filed on Dec. 30, 2021.

(51) Int. Cl. G01R 31/64; H01G 11/08; G01R 31/00; H01M 10/42

(52) U.S. Cl. CPC G01R 31/64; H01G 11/08; G01R 31/006; H01M 10/4264

(57) ABSTRACT

Systems and methods are provided for supercapacitor testing of supercapacitor-to-electrochemical hybrid systems in electric vehicles. Such systems may include an electrochemical battery, supercapacitor adder module, and connections supercapacitor testing module units. The supercapacitor adder module may measure the supercapacitor batteries and determine how to maximize the electrochemical battery use in electric vehicles.

### CROSS-REFERENCE TO RELATED APPLICATIONS

The present patent application claims the priority benefit of U.S. provisional patent application No. 63/295,427 filed Dec. 30, 2021, the disclosure of which is incorporated by reference herein.

### BACKGROUND OF THE INVENTION

### 1. Field of the Disclosure

The present disclosure is generally related to supercapacitor testing, specifically in supercapacitor-to-electrochemical hybrid systems.

### 2. Description of the Related Art

Electric vehicles (EVs) technologies have grown and evolved exponentially in recent years, and a need for facilitating interaction with the EVs has also greatly increased over the recent years. EVs, also referred to as battery EVs, generally use a battery pack to store electrical energy that powers a motor of an EV. Further, electric vehicle battery packs are charged by plugging the vehicle into an electric power source. This electric power source may include an external power source or a power charging station. In recent years, there has been a huge increase in the use of electric propulsion in road transport applications, with internal combustion engine hybrid, battery-electric, and fuel cell vehicles with spark-ignition engine hybrids being the most common. This has opened up an opportunity for regenerative braking, whereby the kinetic energy of a vehicle is converted and stored into electrical energy during braking and recycled to reduce fuel consumption in diesel and fuel cell vehicles and extend the range in battery electric vehicles. Batteries are a popular choice due to the widespread use of batteries in hybrid and electric vehicles.

Because electric vehicles rely on batteries for power, improving battery usage may result in enhancing the performance of electric vehicles. Present technologies are limited, however, in relation to testing supercapacitor batteries installed in electric vehicles, which further limits the ability to determine how best to optimize the charging, enhance lifespans of such batteries in electric vehicles, and maximize supercapacitor battery use in electric vehicles.

There is therefore a need in the art for improved systems and methods of supercapacitor testing for supercapacitor-to-electrochemical hybrid systems.

### SUMMARY OF THE CLAIMED SUBJECT MATTER

Embodiments of the present invention include systems and methods for supercapacitor testing of supercapacitor-to-electrochemical hybrid systems in electric vehicles. Such systems may include an electrochemical battery, supercapacitor adder module, and connections supercapacitor testing module units. The supercapacitor adder module may measure the supercapacitor batteries and determine how to maximize the electrochemical battery use in electric vehicles.

### BRIEF DESCRIPTIONS OF THE DRAWINGS

FIG. 1 illustrates an exemplary network environment in which as a supercapacitor-to-electrochemical hybrid system with supercapacitor testing capability may be implemented.

FIG. 2 is a flowchart illustrating an exemplary method for supercapacitor testing in supercapacitor-to-electrochemical hybrid systems.

FIG. 3 is a flowchart illustrating an exemplary method for supercapacitor control.

FIG. 4 is a flowchart illustrating an exemplary method for supercapacitor testing.

FIG. 5 is a flowchart illustrating an exemplary method for initiating mobile testing.

FIG. 6 is a flowchart illustrating an exemplary method for mobile testing.

### DETAILED DESCRIPTION

Embodiments of the present invention include systems and methods for supercapacitor testing of supercapacitor-to-electrochemical hybrid systems in electric vehicles. Such systems may include an electrochemical battery, supercapacitor adder module, and connections supercapacitor testing module units. The supercapacitor adder module may measure the supercapacitor batteries and determine how to maximize the electrochemical battery use in electric vehicles.

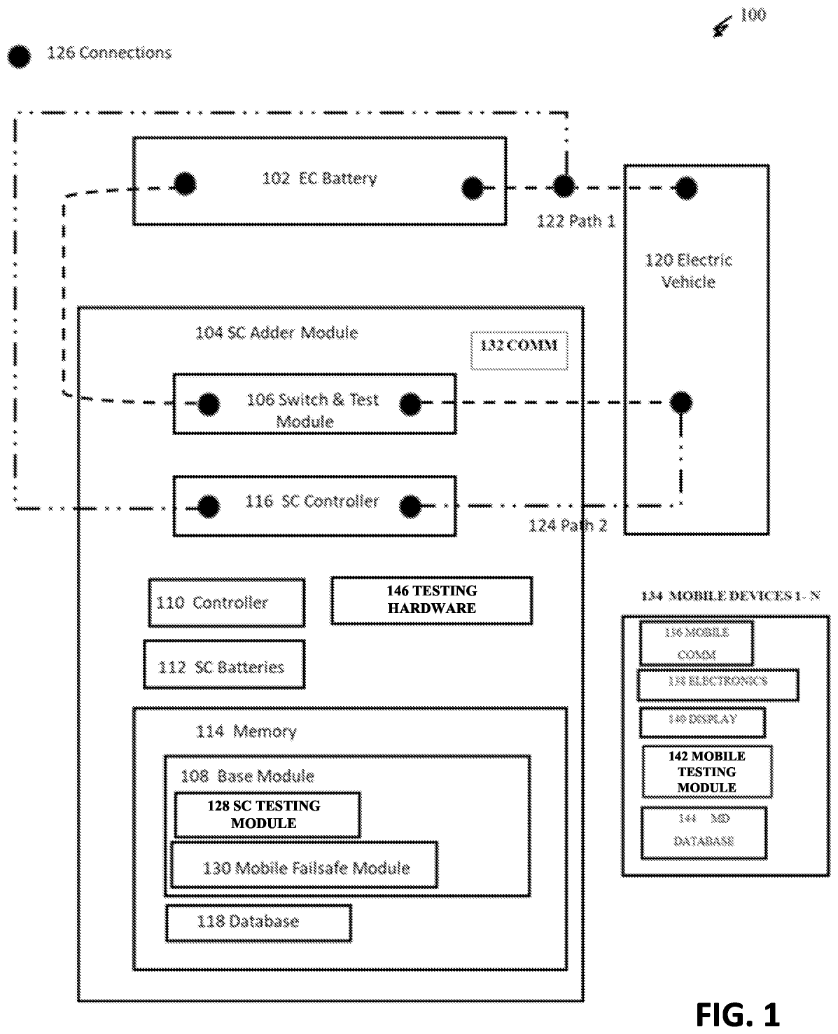

FIG. 1 illustrates an exemplary network environment in which as a supercapacitor-to-electrochemical hybrid system with supercapacitor testing capability may be implemented. As illustrated, the network environment 100 may include electrochemical battery 102, supercapacitor adder module 104, switch & test module 106, base module 108, controller 110, supercapacitor batteries 112, memory 114, database 118, electric vehicle system 120, path 1 122, path 2 124, connections 126, supercapacitor testing 128, mobile failsafe module 130, communication interface 132, mobile devices 1-N 134 (including module communication interface 136, electronic 138, display 140, mobile testing module 142, and mobile device database 144), and failsafe hardware 146.

Electric vehicle system 120 may be installed in or otherwise associated with an electric vehicle, which may correspond to (but is not limited to) a golf cart, an electric car, and an electric bike. Electric vehicle system 120 may include supercapacitor or energy storage units (ESU) (which may be part of a modular power pack), such as supercapacitor batteries 112. Supercapacitor batteries 112 may be inclusive of any type or group of supercapacitor batteries designed to have enough capacity to enhance the integration of supercapacitor adder module 104 and electrochemical battery 102 and designed to be the same voltage as electrochemical battery 102 to integrate into electric vehicle system 120 easily.

Electric vehicle system 120 may be configured to control and enhance capability of the supercapacitor batteries 112, as well as provide a smart energy management system to supply electric charge to the vehicle motor from supercapacitors or supercapacitor batteries 112 in a controlled manner to maximize charge efficiency. Further, the supercapacitor batteries 112 may provide ultra-capacitors with real-time charging and discharging while the electric vehicle is continuously accelerating and decelerating along a predefined path. In one embodiment, the supercapacitor batteries 112 may be inclusive of a modular graphene supercapacitor power pack for powering the electric vehicle. The supercapacitor adder module 104 may be a self-contained unit of all the components shown in one container that may fit inside a battery compartment usually designed to house lead-acid lithium-based batteries. Because supercapacitor batteries 112 of electric vehicle system 120 may take up less space than lead-acid or lithium-based batteries, more space may be available for enhancement. The supercapacitor batteries 112 of electric vehicle system 120 may be designed to perform most of the functions in its container that might typically be integrated into an electric vehicle. The supercapacitor batteries 112 of electric vehicle system 120 may thus allow electric vehicles that are not optimized or designed for supercapacitor batteries to have a plug-compatible supercapacitor batteries 112 to provide energy and manage the various modules in the base module 108.

The supercapacitor batteries 112 may be inclusive of a device that can store and deliver charge and may include one or more power packs which in turn may include supercapacitor units. The supercapacitor batteries 112 may also include batteries, hybrid systems, fuel cells, etc. Capacitance provided in the components of the supercapacitor batteries 112 may be in the form of electrostatic capacitance, pseudocapacitance, electrolytic capacitance, electronic double-layer capacitance, and electrochemical capacitance, and a combination thereof, such as both electrostatic double-layer capacitance and electrochemical pseudocapacitance, as may occur in supercapacitors. The supercapacitor batteries 112 may be associated with or include control hardware and software with suitable sensors, as needed, for an energy control system to manage any of the following: temperature control, discharging of the supercapacitor batteries 112 whether collectively or of any of its components, charging of the supercapacitor batteries 112 whether collectively or of any of its components, maintenance, interaction with batteries, battery emulation, communication with other devices, including devices that are directly connected, adjacent, or remotely such as by wireless communication, etc. In some aspects, the supercapacitor batteries 112 may be portable and provided in a casing containing at least some components of the energy control system and features such as communication interface 132, etc.

Supercapacitor units may include an ultracapacitor, which is an electrical component capable of holding hundreds of times more electrical charge quantity than a standard capacitor. This characteristic makes ultracapacitors useful in devices that require relatively little current and low voltage. In some situations, an ultracapacitor can take the place of a rechargeable low-voltage electrochemical battery.

Supercapacitor units (including ultracapacitors) typically have high power density, meaning they can charge up quickly and discharge quickly. The load curve of a chemical battery typically shows a high energy density, meaning such battery is very stable upon discharge (e.g., voltage does not change much over time for a given load) for long periods of time. This means that the chemical battery (lead acid or lithium ion etc) has a high energy density but they have a low power density, meaning they charge slowly. Ultracapacitors or supercapacitors units have been developed recently that have both a high power density (charge fast) and a high energy density (discharge slowly). An ultracapacitor or supercapacitor unit that has both a high power density and a high energy density with a load discharge curve that resembles or comes close to a load discharge curve of a chemical battery, is ideal. As used herein, supercapacitor refers generically to all forms of supercapacitors, but ideally one that has both high power density as well as high energy density.

The energy control system may combine hardware and software (e.g., one or more modules 106/108/128/130) that manages various aspects of the supercapacitor batteries 112, including its energy to the device. The energy control system regulates the supercapacitor batteries 112 to control discharging and charging (whether collectively or of any of its components), and other features as desired, such as temperature, safety, efficiency, temperature control, maintenance, interaction with batteries, or battery emulation, communication with other devices, including devices that are directly connected, adjacent, or remotely such as by wireless communication, etc. The supercapacitor batteries 112 may be adapted to give the energy control system individual control over each power pack or optionally over each supercapacitor or grouped supercapacitor unit to tap the available power of individual supercapacitors efficiently and to properly charge individual supercapacitors rather than merely providing a single level of charge for the supercapacitor batteries 112 as a whole that may be too little or too much for individual supercapacitors or their power packs.

The energy control system may include one or more modules that a processor (e.g., controller 110) can execute or govern according to code stored in a memory 114 such as a chip, a hard drive, a cloud-based source, or another computer-readable medium. Thus, the energy control system may include or be operatively associated with a processor, a memory 114 that includes code for the controller (e.g., modules 106/108/128/130), a database 118, and communication tools such as a bus or wireless capabilities for interacting with a communication interface 132 or other components or otherwise providing information, information requests, or commands. The energy control system may interact with individual power packs or supercapacitors through a crosspoint switch or other matrix systems. Further, the energy control system may obtain information from individual power packs or their supercapacitors through similar switching mechanisms or direct wiring in which, for example, one or more of a voltage detection circuit, an amperage detection circuit, a temperature sensor, and other sensors or devices may be used to provide details on the level of charge and performance of the individual power pack or supercapacitor.

As illustrated, supercapacitor batteries 112 may correspond to supercapacitor units of supercapacitor batteries 112, which may be inclusive of, for example, is a 21,000F 4.2V nano-pouch graphene energy module with a final 48V 100AH Graphene Power Pack. The 21,000F 4.2V nano-pouch graphene energy modules may contain many layers of a graphene lattice matrix structure deposited using a unique method of electropolymerization that provides a highly dense energy storage module design with high-current energy transfer. Due to the tightly coupled nanotechnology design and manufacturing methods, energy storage and delivery can be cycled thousands of times without matrix degradation. This power pack is a capacitive battery substitute in nature, graphene-based, and contains no lithium or other chemical conversion components. In one embodiment, the plurality of supercapacitor batteries 112 may be continuously charged in real-time, depending upon the usage of the electric vehicle system 120, such as through the use of solar panels, inductive charging, etc., and optionally by redistributing charge among individual supercapacitors or supercapacitor units (a single supercapacitor unit or multiple supercapacitor batteries 112 may include multiple supercapacitors internally). Alternatively or in addition, supercapacitor batteries 112 may be charged while connected to a suitable charging source such as an AC power line (not shown) or DC power (not shown) n alternative energy source such as solar power, wind power, etc., where a trickle charging system may be applied.

The charging and discharging hardware of supercapacitor batteries 112 may include the wiring, switches, charge detection circuits, current detection circuits, and other devices for proper control of charge applied to the power packs or the batteries or other energy storage units and temperature-control devices such as active cooling equipment and other safety devices. Active cooling devices (not shown) may include fans, circulating heat transfer fluids that pass through tubing or, in some cases, surround or immerse the power packs, thermoelectric cooling such as Peltier effect coolers, etc.

To charge and discharge an individual unit among the power packs to optimize the overall efficiency of the supercapacitor batteries 112, methods are needed to select one or more of many units from what may be a three-dimensional or two-dimensional array of connectors to the individual units. Any suitable methods and devices may be used for such operations, including crosspoint switches or other matrix switching tools. Crosspoint switches and matrix switches are means of selectively connecting specific lines among many possibilities, such as an array of X lines (X1, X2, X3, etc.) and an array of Y lines (Y1, Y2, Y3, etc.) that may respectively have access to the negative or positive electrodes or terminals of the individual units among the power packs as well as the batteries or other energy storage units. SPST (Single-Pole Single-Throw) relays, for example, may be used. By applying a charge to individual supercapacitors within power packs or to individual power packs within the supercapacitor batteries 112, a charge can be applied directly to where it is needed, and a supercapacitor or power pack can be charged to an optimum level independently of other power packs or supercapacitors.

Meanwhile, electrochemical battery 102 may be inclusive of any electrochemical battery known in the art, such as lead-acid or lithium-ion, etc. Electrochemical batter 102 may be connected respectively to electric vehicle system 120 (via path 1 122) and supercapacitor adder module 104.

Supercapacitor adder module 104 is a self-contained unit with various connections 126, including connections to electrochemical battery 102 and electric vehicle system 120. Supercapacitor adder module 104 has a higher capacity and deliver charges at a much smaller weight and size in comparison to electrochemical batteries 102. As illustrated, supercapacitor adder module 104 may include supercapacitor batteries 112 and contain a supercapacitor controller 116 or other control system to switch between electrochemical battery 102 and supercapacitor batteries 112 automatically. There may be many reasons to switch between electrochemical battery 102 and supercapacitor batteries 112 and vice versa. In one embodiment, a switch between electrochemical battery 102 and supercapacitor batteries 112 could allow supercapacitor batteries 112 to power an electric vehicle when many amperages are demanded quickly (e.g., moving up a steep hill). In another implementations, switching between an electrochemical battery 102, and supercapacitor battery 112 may be performed to prolong the life of the electrochemical battery 102. Supercapacitor adder module 104 may further be executable to apply artificial intelligence and machine learning to model battery efficiency under various conditions and predict which switching actions may result in improved efficiency of the batteries, improved performance of the electric vehicle, or improvement in other performance metrics.

The supercapacitor adder module 104 may be small enough to fit into the existing battery compartments of an electric vehicle. Supercapacitor adder module 104 may be designed to easily connect to electrochemical battery 102 and electric vehicle system 120 using standard battery connections shown as connections 126 and wiring involved in either path 1 122 or path 2 124. Wiring layout of path 1 122 and path 2 124 may be one example of how switching could occur, but there could be many others depending upon how supercapacitor adder module 104 is designed and configured. In another embodiment, the reason to switch from an electrochemical battery 102 and supercapacitor battery 112 or vice versa would be to reduce the number of charging cycles of electrochemical batteries. In another embodiment, the reason to switch from an electrochemical battery 102 and supercapacitor battery 112 or vice versa would be to use the greater electrical charge that supercapacitors have. In other embodiments, switching from an electrochemical battery 102 and supercapacitor battery 112 or vice versa would optimize discharge, as the discharge is faster for supercapacitor battery 112. In another embodiment, the reason to switch from an electrochemical battery 102 and supercapacitor battery 112 or vice versa would be to enhance the long-term power storage of electrochemical batteries. In another embodiment, the reason to switch from an electrochemical battery 102 and supercapacitor battery 112 or vice versa would be to enhance the lifespan of electrochemical batteries as supercapacitors can go a million charge cycles before it starts to degrade, whereas electrochemical batteries like lead-acid batteries may only get 500 to 1,000 charge cycles before degrading. In this embodiment, the supercapacitor adder module 104 is only used for testing supercapacitor batteries 112.

Further, switch & test module 106 allows amperage measurement in path 1 to see how much amperage is drawn through electrochemical battery 102 and electric vehicle system 120. switch & test module 106 can also be instructed to disconnect or connect electrochemical battery 102 using a digitally controlled high-powered relay. Switch & test module 106 can also operate in milliseconds, so that switching may not cause electric vehicle 102 smooth operation. In this embodiment, the switch & test module 106 is not used for testing supercapacitor batteries 112.

Base module 108 may be communicatively coupled to a processor (e.g., controller 110) and may reside in whole or in part in memory 114. In one embodiment, the base module 108 may act as a central module to receive and send instructions to/from each of the other modules 104/106/128/130. In one embodiment, the base module 108 may be configured to manage at least two parameters related to the electric vehicle system 102, such as, but are not limited to, electric charge of the plurality of supercapacitor batteries 112 and the performance of the electric vehicle upon receipt of a predefined amount of electric charge from the plurality of supercapacitor batteries 112. In some implementations, base module 108 may be executable to disconnect electrochemical battery 102 and perform tests on supercapacitor battery 112.

Controller 110 may be inclusive of one or more processors that execute commands, including software instructions in memory 114 (e.g., from base module 108 or other modules 104/106/128/130). Execution of such instructions by the controller 110 may further result in generation and communication of generated instructions to the electric vehicle system 120, the plurality of supercapacitor batteries 112 (e.g., based on information from database 118), the terrain or route, and other parameters via the cloud communication network and other remote sources (e.g., remote databases). In one embodiment, the retrieved information related to the electric vehicle system 120 may be stored in real-time into the memory 114. Controller 110 could further generate and refine learning models regarding electric vehicle controls and operations (including supercapacitor performance) in many ways, including but not limited to application of artificial intelligence/machine learning of historical data (including historical data from other electric vehicles, users, operating conditions, past actions and associated performance), etc. As such, beyond relying on static information in databases, in some aspects, the controller 110 may be adapted to perform machine learning and to learn from situations faced constantly. In related aspects, the controller 110 and the associated software (e.g., modules 104/106/108/128/130) may form a “smart” controller based on machine learning or artificial intelligence adapted to handle a wide range of input and a wide range of operational demands.

In exemplary implementations, controller 110 allows access (reading and writing the database 118 and allows instruction to turn on and off switch & test module 106 and supercapacitor controller 116. In exemplary implementations, controller 110 also allows for current measurements from path 1 or path 2 to be collected and stored (in real-time) in database 118. Controller 110 also controls the switching of the high-powered switching relay in path 1 and path 2 as the base module executes. In this embodiment, path 1 122 is not used to test supercapacitor batteries 112.

Memory 114 is designed to operate the storage of base module 108 and its sub-modules (e.g., modules 104/106/108/128/130) and database 118. Memory 114 may store coding for operation of one or more of the modules 104/106/108/128/130) and their interactions with each other or other components. Memory 118 may also include information such as database 118 pertaining to any aspect of the operation of the electric vehicle system 120, though additional databases may also be available via the cloud/communication network. The memory 114 may store data in one or more locations or components such as a memory chip, a hard drive, a cloud-based source or other computer readable medium, and may be in any useful form such as flash memory, EPROM, EEPROM, PROM, MROM, etc., or combinations thereof and in consolidated (centralized) or distributed forms. The memory may in whole or in part be read-only memory (ROM) or random-access memory (RAM), including static RAM (SRAM), dynamic RAM (DRAM), synchronous dynamic RAM (SDRAM), and magneto-resistive RAM (MRAM), etc.

Such databases stored in memory 114 can include a database 118 that stores data regarding the electric vehicle, such as various charge management parameters relating to the charging and/or discharging characteristics of a plurality or all of the energy sources (the power packs and the batteries or other energy storage units) for guiding charging, discharging, and switching operations. Such data may also be included with energy-source-specific data provided by or accessed by the modules 104/106/108/128/130.

In exemplary implementations, database 118 allows reading and writing data from base module 108 and their sub-modules and data associated with switch & test module 116 and supercapacitor controller 116. Database 118 also stores the recommended max charging energy or amperage for supercapacitor batteries 112. It should be understood that Supercapacitor adder module 104 units can have many different supercapacitor batteries 112, so this charging data is essential for safety and performance. Database 118 also stores data and prestored thresholds for testing supercapacitor batteries 112, such as ESR, capacitance, leakage, other S Battery tests, all actions, and AI correlations.

Path 1 122 shows connections between electric vehicle system 120 and electrochemical battery 102, which is interrupted by the insertion of supercapacitor adder module 104. In this embodiment, path 1 122 is not used to test supercapacitor batteries 112.

Path 2 124 shows connections between electric vehicle system 120 and supercapacitor Controller 116, allowing the flow of charge from supercapacitor batteries 112 to electric vehicle system 120.

Connection 126 shows terminals (such as battery terminals) connecting Supercapacitor adder module 104 into the system 100.

Supercapacitor testing module 128 may be executable (e.g., from base module 108) to perform various supercapacitor testing operations, such as measuring amperage flowing through path 1 between electrochemical battery 102 and electric vehicle system 120 and path 2 supercapacitor batteries 112 and electric vehicle system 120. Further, the supercapacitor testing module 128 may store such amperage measurements in database 118.

The supercapacitor testing module 128 may further be executable to identify the equivalent series resistance (ESR) of supercapacitor batteries 112 using testing hardware 146 and to store such measurements and related data in database 118, along with a time stamp. ESR in the supercapacitor cell may come from two things: materials used and design. The composition of materials used—e.g., carbons, graphene, conductive carbons, binders, separator, and electrolyte—may affect an ESR level measurement. The thickness of the electrode may also affect the ESR. The cell design in the electrodes attached to the terminals drives the cell ESR numbers. The lowest ESR is achieved using properly designed materials with good connections to the terminals.

Often, however, analyses by supercapacitor testing module 128 may need to look at how the ESR increases over time rather than the initial rating. The increase in ESR is typically used to determine the system performance at the end of life, and just because a cell has low ESR when it is new, it does not mean it may stay low. Cycling, time spent at temperature, and voltage all play a role in increasing ESR. Some manufactures have improved this ESR gain significantly by using better materials. Lastly, since almost no ultracapacitor is used alone, the module construction and design drive a significant part of the ESR seen at a system level at step 406. Further, the supercapacitor testing module 128 calculates the capacitance of supercapacitor batteries 112 using testing hardware 146 and stores data in database 118 along with a time stamp. Supercapacitors are different from other types of capacitors when measuring their capacitance. They have substantial capacitance values that standard equipment cannot directly measure. The typical way to test these capacitances is using a ‘charging and discharging method. This includes charging the supercapacitor for 30 minutes at rated voltage and then discharging the supercapacitor through a constant current load.

Supercapacitor testing module 128 may be further executable to measure the voltage drop between two voltage levels (e.g., V1 and V2). The discharging time between V1 and V2, Time in seconds is measured, and capacitance is calculated as =I*T(sec)/(V1−V2), where I discharge current=1×C (in Faradays) at step 408. Further, the supercapacitor testing module 128 calculates leakage current and self-discharge rate of supercapacitor batteries 112 using testing hardware 146 and stores data in database 118 along with the timestamp. Leakage current is a supercapacitor non-ideality. A well-functioning capacitor may be able to maintain constant voltage without current flow from an external circuit. Real capacitors require current (e.g., leakage current) to maintain a constant voltage.

Leakage current can be modeled as a resistance in parallel with the capacitor. This model oversimplifies the voltage-and time dependence of leakage current. Leakage current discharges a charged capacitor with no external connections to its terminals. This process is called self-discharge. Note that a leakage current of 1 μA on a 1 F capacitor held at 2.5 V implies a 2.5 MΩ leakage resistance. The time constant for the self-discharge process on this capacitor is 2.5×106 seconds—nearly a month. Further, supercapacitor testing module 128 calculates other tests on supercapacitor Batteries 112 using testing hardware 146 to date and stores data on database 118 along with a timestamp. Many other tests can be tested on supercapacitor, such as but not limited to (1) cycle time, (2) electrochemical impedance spectroscopy, (3) capacitor-voltage relationships, and (4) energy density.

Mobile failsafe module 130 may be executed by controller 110 (e.g., as prompted by instructions from base module 108) to connect to mobile devices 1-n 134 mobile communication interface 136 and to synchronize data between database 118 and mobile device database 144. Mobile failsafe module 130 may determine whether there is any data to synchronize by polling mobile devices 1-N 134 for communications sent from mobile communication interface 136.

Communication interface 132 allows the communication between the supercapacitor adder module 104 and mobile device 1-N 134. The communication interface 132 is a hardware device and software that executes any plurality of types of communication, from WiFi, Zigbee, BLUETOOTH, cellular, etc.

Mobile device 1-N 134 represents numerous users of mobile devices, such as smartphones, tablets, PCs, etc. Mobile communication interface 136 allows the communication from the mobile device 1-N 134 to supercapacitor adder module 104 via communication interface 132. The mobile communication interface 132 is a hardware device and software that executes a plurality of types of communication, from WiFi, Zigbee, BLUETOOTH, cellular, etc.

Electronics 138 of mobile device 134 includes all the hardware and software that allows mobile device 134 to operate, which may be inclusive of processors (similar to controller 110), memory (similar to memory 114), and display interfaces. For example, display 140 of mobile device 134 may be a display screen or touchscreen that displays graphic user interface displays and that receives user input from a user of the mobile device 134.

Further, mobile testing module 142 may be executed (e.g., in response to being called from supercapacitor adder module 104 via mobile failsafe module 130 where Database 118 is synchronized with mobile device database 144. In such implementations, other tests may have been performed, including (1) testing equivalent series resistance (esr), (2) capacitance testing, (3) testing leakage current and self-discharge, and (4) other testing has been done. Mobile testing module 142 may displays to the user on display 140 test results and other data regarding such tests (e.g., by the type of testing) (1) testing equivalent series resistance (ESR), (2) capacitance testing, (3) testing leakage current and self-discharge, and (4) other testing. Mobile testing module 142 allows users to run other supercapacitor capacitor tests. Mobile testing module 142 determines if any supercapacitor tests cause safety concerns. Write “safety concerns” and time stamp to mobile device database 144.

Mobile testing module 142 may further be executable to determine if testing leakage current and self-discharge show high rates (e.g., beyond a threshold), then write “high leakage” and timestamp to mobile device database 144. Mobile testing module 142 saves all data to mobile device database 144 and synchronizes all data between mobile device database 144 and database 118. Mobile testing module 142 may further connects to a third party network and local or remote network databases through mobile communication interface 136, cloud (or other communication network). Mobile testing module 142 may also synchronize all data between mobile device database 144 and database 118, use AI to evaluate correlations between historical data (e.g., from database 118 and/or third party network databases) and mobile device database 144. For example, the database 118 may have data indicative of a high correlation between high leakage and high ESR with a trend that shows that supercapacitor batteries are predicted to fail soon.

If any correlations are found, mobile testing module 142 may generate a display illustrating the correlations on display 140, as well as one or more recommendations for actions responsive to such trends, correlations, or predictions. Mobile testing module 142 may further allow users to write “normal” and timestamp to mobile device database 144 if all tests are within ranges. There are no safety concerns and no unusual AI correlations. Mobile testing module 142 allows users to write “AI Correlations” and timestamp to mobile device database 144 if a correlation is found. Mobile testing module 142 synchronizes all mobile device database 144, third party network 150, and supercapacitor adder module 104 database 118. Mobile testing module 142 returns to mobile failsafe module 130 of supercapacitor adder module 104.

Mobile device database 144 allows for reading and writing all data related to the mobile testing module 142 and is synchronized with database 118.

Testing hardware 146 is controlled via controller 110 and the base module 108 (as well as other modules called by the base module). Tests for equivalent series resistance, capacitance, high leakage, and other supercapacitor testing can be applied directly to supercapacitor batteries 112.

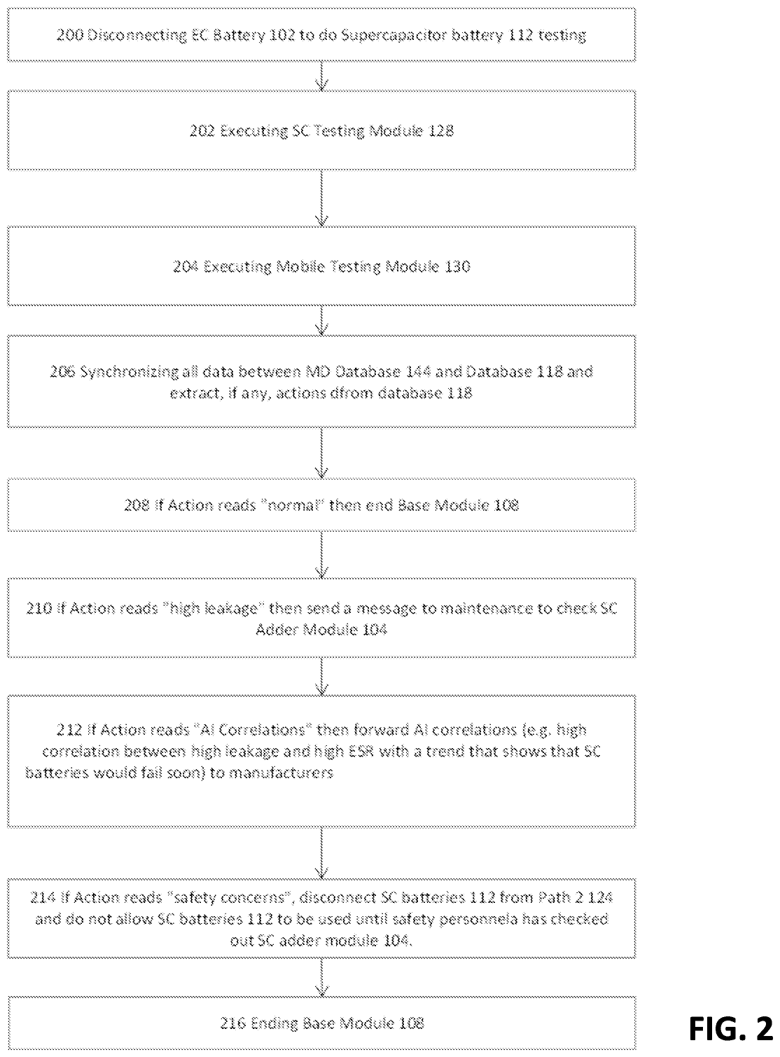

FIG. 2 is a flowchart illustrating an exemplary method for supercapacitor testing in supercapacitor-to-electrochemical hybrid systems, which may be performed when base module 108 is executed by an associated processor or controller 110. One skilled in the art may appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

At step 200, switch & test module 106 and electric vehicle system 120 and path 1 122 are not used during tests, and base module 108 may disconnect electrochemical battery 102 to do supercapacitor battery 112 tests.

Base module 108 then executes supercapacitor testing module 128 at step 202. Base module 108 then executes mobile failsafe module 130 at step 204. Base module 108 synchronizes all data between mobile device database 144 and database 118 and extracts actions from database 118 at step 206. Base module 108 determines if action reads “normal” then end Base Module 108 at step 208. Base module 108 determines if action reads “high leakage,” then sends a message to maintenance to check supercapacitor adder module 104 at step 210. Base module 108 determines if action reads “AI Correlations” then forward AI correlations (e.g., a high correlation between high leakage and high ESR with a trend that shows that supercapacitor batteries would fail soon) to manufacturers attached to a third party network at step 212. Base module 108 determines if action reads “safety concerns,” disconnect supercapacitor batteries 112 from path 2 124, and do not allow supercapacitor batteries 112 to be used until safety personnel has checked out supercapacitor adder module 104 at step 214. One or more notifications may be sent to designated recipient devices based on the determined action. Base module 108 ends at step 216.

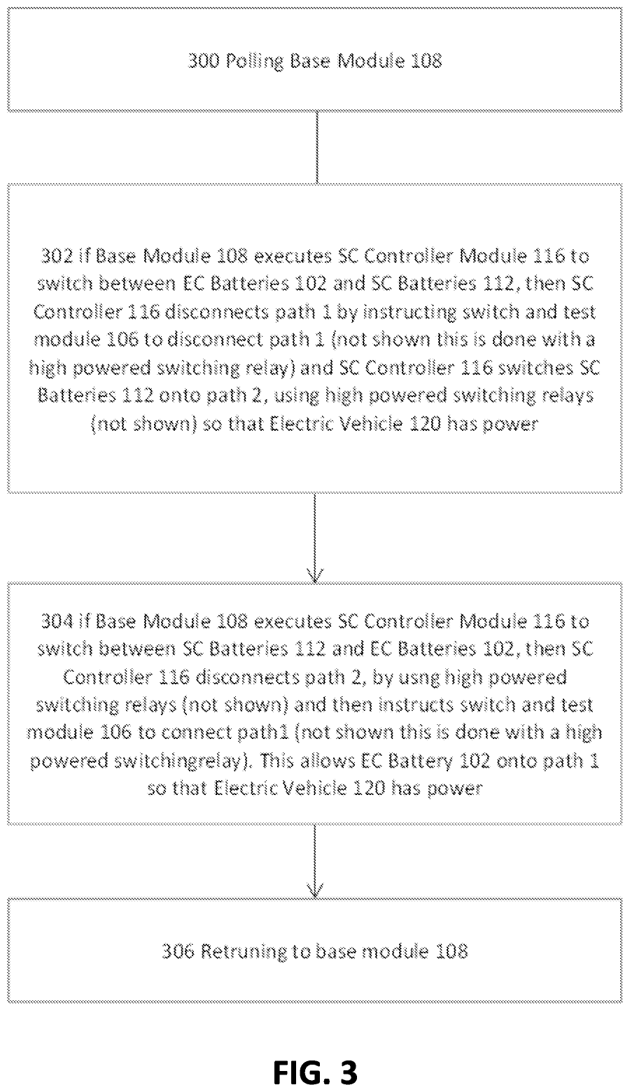

FIG. 3 is a flowchart illustrating an exemplary method for supercapacitor control, which may be performed based on execution of supercapacitor controller 116 by controller 110 (e.g., in response to call or instruction from base module 108).

At step 300, supercapacitor controller 116 polls base module 108 to determine if base module 108 has provided instruction to switch between electrochemical batteries 102 and supercapacitor batteries 112.

Then supercapacitor controller 116 disconnects path 1 122 by instructing switch & test module 106 to disconnect path 1 (not shown this is done with a high-powered switching relay) and supercapacitor controller 116 switches supercapacitor batteries 112 onto path 2, using high powered switching relays (not shown) so that electric vehicle system 120 has power at step 302.

Supercapacitor controller 116 determines if base module 108 executes supercapacitor controller module 116 to switch between supercapacitor batteries 112 and electrochemical batteries 102. Supercapacitor controller 116 disconnects path 2 124 using high-powered switching relays (not shown) and then instructs switch & test module 106 to connect path 1 122 (e.g., using a high-powered switching relay). This allows electrochemical battery 102 onto path 1 so that electric vehicle system 120 has power at step 304. supercapacitor controller module 116 then returns control to base module 108 at step 306. In this embodiment, path 1 122 is not used to test supercapacitor batteries 112.

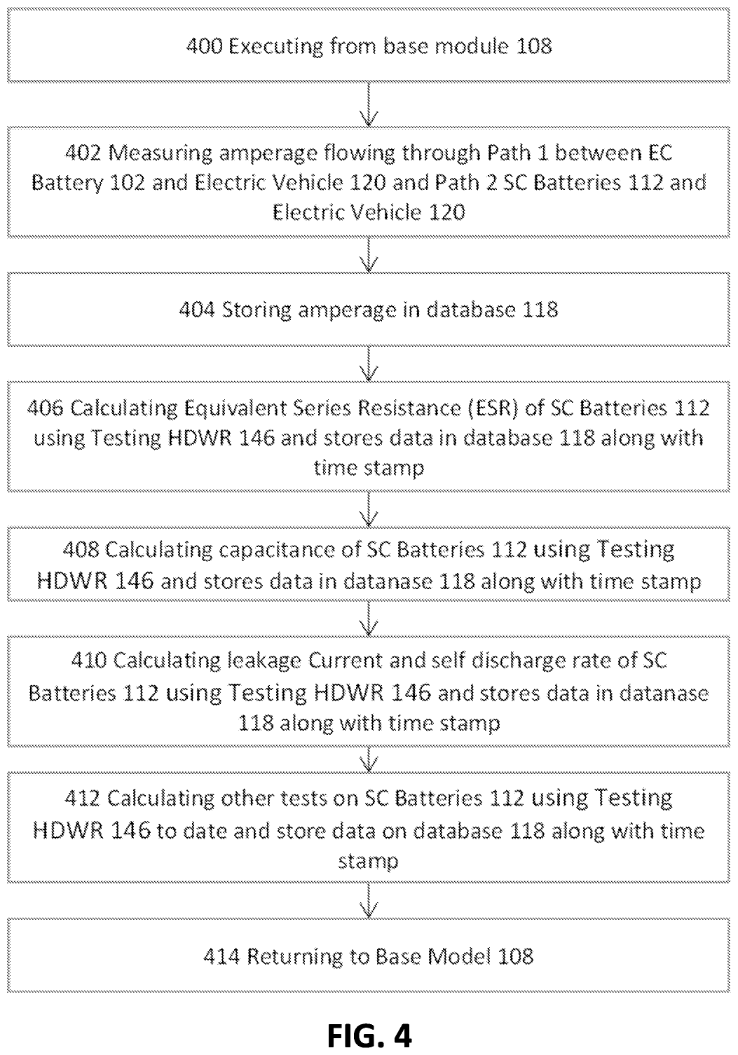

FIG. 4 is a flowchart illustrating an exemplary method for supercapacitor testing, which may be performed based on execution of supercapacitor testing module 128 by controller 110

The process begins with the supercapacitor Testing Module 128 executes from base module 108 at step 400. At step 402, the supercapacitor testing module 128 measures amperage, flowing through path 1 122 between electrochemical battery 102 and electric vehicle system 120 and through path 2 124 between supercapacitor batteries 112 and electric vehicle system 120.

The supercapacitor testing module 128 may store the amperage measurements in database 118 at step 404. Further, the supercapacitor testing module 128 may calculate the equivalent series resistance (ESR) of supercapacitor batteries 112 using testing hardware 146 and stores data in database 118 along with a time stamp at step 406.

The discharging time between V1 and V2, time in seconds is measured, and capacitance is calculated as =I*T(sec)/(V1−V2), where I discharge current=1×C (in Faradays) at step 408. Further, the supercapacitor testing module 128 calculates leakage current and self-discharge rate of supercapacitor batteries 112 using testing hardware 146 and stores data in database 118 along with the timestamp at step 410.

Further, at step 412, supercapacitor testing module 128 calculates other tests on supercapacitor Batteries 112 using testing hardware 146 to date and stores data on database 118 along with a timestamp. Such tests for supercapacitors may include (1) cycle time, (2) electrochemical impedance spectroscopy, (3) capacitor-voltage relationships, and (4) energy density. The supercapacitor testing module 128 returns to base module 108 at step 414.

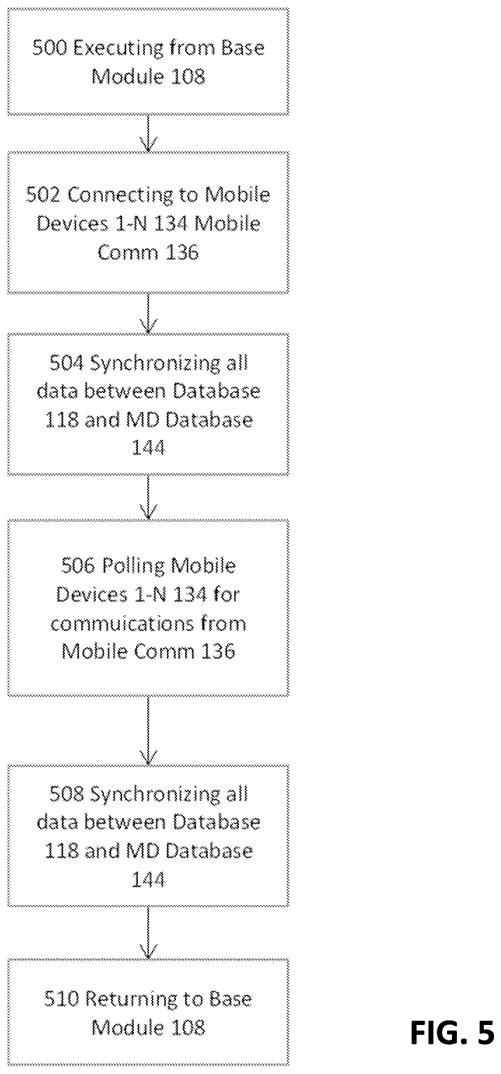

FIG. 5 is a flowchart illustrating an exemplary method for initiating mobile testing, which may be performed based on execution of mobile failsafe module 130 by controller 110 (e.g., in response to instruction from base module 108).

The process begins with mobile failsafe module 130 executes from base module 108 at step 500. Mobile failsafe module 130 connects to mobile devices 1-n 134 mobile communication interface 136 at step 502. Mobile failsafe module 130 synchronizes all data between database 118 and mobile device database 144 at step 504. Mobile failsafe module 130 polls mobile devices 1-N 134 for communications from mobile communication interface 136 at step 506. Mobile failsafe module 130 synchronizes all data between database 118 and mobile device database 144 at step 508. Mobile failsafe module 130 returns to base module 108 at step 510.

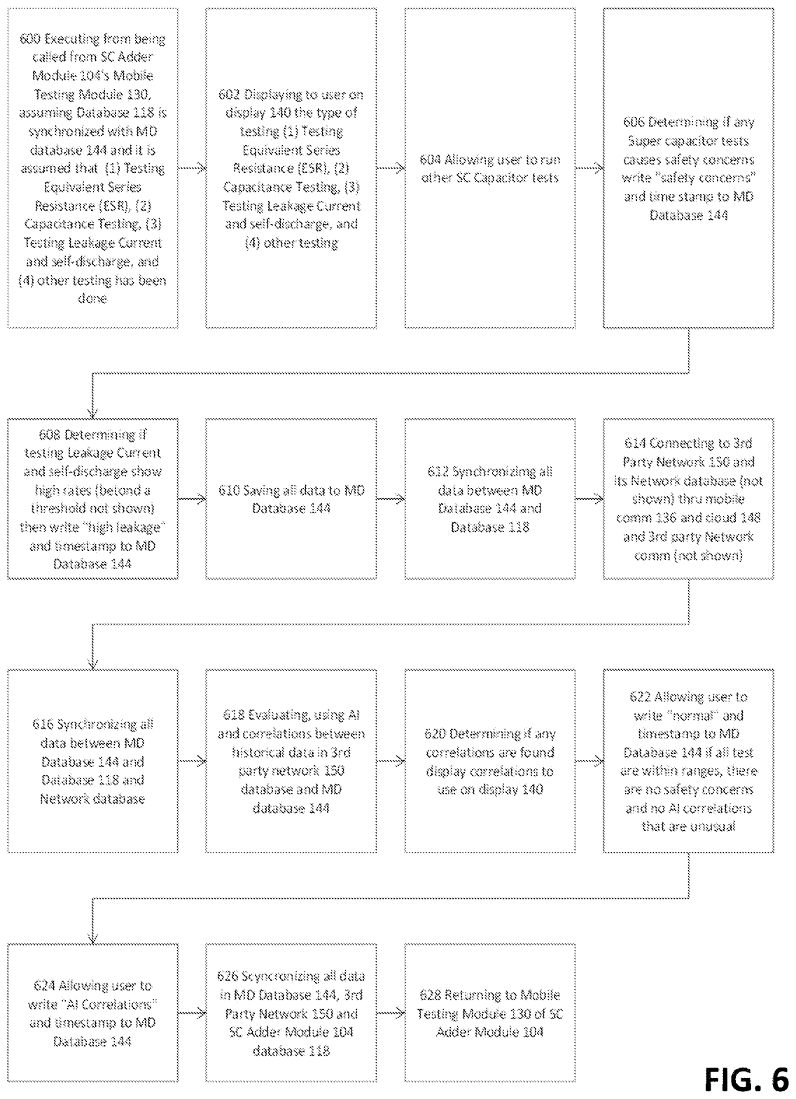

FIG. 6 is a flowchart illustrating an exemplary method for mobile testing, which may performed based on execution of mobile testing module 142 by a processor (e.g., mobile device electronics 138).

The process begins with mobile testing module 142 executes from being called from supercapacitor adder module 104′s mobile failsafe module 130, assuming database 118 is synchronized with mobile device database 144. It is assumed that (1) testing equivalent series resistance (esr), (2) capacitance testing, (3) testing leakage current and self-discharge, and (4) other testing has been done at step 600.

Mobile testing module 142 displays to the user on display 140 the type of testing (1) Testing Equivalent Series Resistance (ESR), (2) Capacitance Testing, (3) Testing Leakage Current and self-discharge, and (4) other testing at step 602. Mobile testing module 142 allows users to run other supercapacitor Capacitor tests at step 604. Mobile testing module 142 determines if any Supercapacitor tests cause safety concerns. Write “safety concerns” and time stamp to Mobile device database 144 at step 606.

Mobile testing module 142 determines if testing Leakage Current and self-discharge show high rates (beyond a threshold not shown), then write “high leakage” and timestamp to Mobile device database 144 at step 608. Mobile testing module 142 saves all data to Mobile device database 144 at step 610. Mobile testing module 142 synchronizes all data between Mobile device database 144 and Database 118 at step 612. Mobile testing module 142 connects to third Party Network 150 and its Network database (not shown) through mobile communication interface 136 and cloud 148 and third party Network comm (not shown) at step 614. Mobile testing module 142 synchronizes all data between Mobile device database 144 and Database 118 and Network database at step 616.

Mobile testing module 142 evaluates, using AI and correlations between historical data in third party network 150 databases and Mobile device database 144. For example, the third Party Network 150 database may have seen a high correlation between high leakage and high ESR with a trend that shows that supercapacitor batteries would fail soon, at step 618. Mobile testing module 142, if any correlations are found, display correlations to use on display 140 at step 620. Mobile testing module 142 allows users to write “normal” and timestamp to Mobile device database 144 if all tests are within ranges. There are no safety concerns and no unusual AI correlations at step 622. Mobile testing module 142 allows users to write “AI Correlations” and timestamp to Mobile device database 144 if a correlation is found at step 624. Mobile testing module 142 synchronizes all Mobile device database 144, third Party Network 150, and Supercapacitor adder module 104 database 118 at step 626. Mobile testing module 142 returns to Mobile failsafe module 130 of supercapacitor adder module 104 at step 628.

When listing various aspects of the products, methods, or system described herein, it should be understood that any feature, element or limitation of one aspect, example, or claim may be combined with any other feature, element or limitation of any other aspect when feasible (i.e., not contradictory). Thus, power pack may include a temperature sensor and then a separate example of a power pack associated with an accelerometer would inherently disclose a power pack that includes or is associated with an accelerometer and a temperature sensor.

Unless otherwise indicated, components such as software modules or other modules may be combined into a single module or component, or divided such that the function involves cooperation of two or more components or modules. Identifying an operation or feature as a discrete single entity should be understood to include division or combination such that the effect of the identified component is still achieved.

Embodiments of the present disclosure may be provided as a computer program product, which may include a computer-readable medium tangibly embodying thereon instructions, which may be used to program a computer (or other electronic devices) to perform a process. The computer-readable medium may include, but is not limited to, fixed (hard) drives, magnetic tape, floppy diskettes, optical disks, Compact Disc Read-Only Memories (CD-ROMs), and magneto-optical disks, semiconductor memories, such as ROMs, Random Access Memories (RAMs), Programmable Read-Only Memories (PROMs), Erasable PROMs (EPROMs), Electrically Erasable PROMs (EEPROMs), flash memory, magnetic or optical cards, or other types of media/machine-readable medium suitable for storing electronic instructions (e.g., computer programming code, such as software or firmware). Moreover, embodiments of the present disclosure may also be downloaded as one or more computer program products, wherein the program may be transferred from a remote computer to a requesting computer by way of data signals embodied in a carrier wave or other propagation medium via a communication link (e.g., a modem or network connection).

What is claimed is:

1. A system for supercapacitor testing in electric vehicles, the system comprising:
at least one supercapacitor battery of an electric vehicle;
at least one electrochemical battery of the electric vehicle, wherein the at least one electrochemical provides power to the electric vehicle via a connection;
memory that stores one or more thresholds for supercapacitor performance metrics and one or more recommended actions associated with different supercapacitor states; and
a processor that executes instructions stored in memory, wherein the processor executes the instructions to:
disconnect the at least one electrochemical battery from the electric vehicle by interrupting the connection,
perform one or more tests on the at least one supercapacitor battery, wherein results of the tests include one or more measurements each associated with a timestamp,
identify a current state of the at least one supercapacitor battery based on a comparison of the test results to the thresholds, and
provide one of the recommended actions associated with the current state of the at least one supercapacitor battery to a designated recipient device.

2. The system of claim 1, wherein the connection is controlled by a relay, and wherein the processor disconnects the at least one electrochemical battery using the relay.

3. The system of claim 1, wherein the memory further stores historical data regarding one or more of performance of the at least one supercapacitor, performance of another supercapacitor, operating conditions, past actions, and associated performance metrics.

4. The system of claim 3, wherein the processor executes further instructions to generate learning models regarding supercapacitor performance under a plurality of conditions based on the historical data.

5. The system of claim 4, wherein the processor generates the learning models further based on data from one or more remote databases.

6. The system of claim 4, wherein the processor executes further instructions to apply artificial intelligence to the historical data to identify one or more correlations between the supercapacitor performance and one or more of the conditions.

7. The system of claim 6, wherein the processor executes further instructions to make predictions regarding future performance the at least one supercapacitor battery based on the identified correlations and the current state.

8. The system of claim 6, wherein the processor executes further instructions to generate a display illustrating the correlations.

9. The system of claim 1, wherein the processor identifies a current state of the at least one supercapacitor battery based further on user input.

10. A method for supercapacitor testing in electric vehicles, the method comprising:
storing in memory one or more thresholds for supercapacitor performance metrics and one or more recommended actions associated with different supercapacitor states;
executing instructions stored in memory, wherein execution of the instructions by a processor:
disconnects at least one electrochemical battery of an electric vehicle, wherein the at least one electrochemical provides power to the electric vehicle via a connection, and wherein disconnecting the at least one electrochemical battery includes interrupting the connection,
performs one or more tests on at least one supercapacitor battery of the electric vehicle, wherein results of the tests include one or more measurements each associated with a timestamp,
identifies a current state of the at least one supercapacitor battery based on a comparison of the test results to the thresholds, and
provides one of the recommended actions associated with the current state of the at least one supercapacitor battery to a designated recipient device.

11. The method of claim 10, wherein the connection is controlled by a relay, and wherein the disconnecting the at least one electrochemical battery includes using the relay.

12. The method of claim 1, further comprising storing historical data in memory regarding one or more of performance of the at least one supercapacitor, performance of another supercapacitor, operating conditions, past actions, and associated performance metrics.

13. The method of claim 12, further comprising generating learning models regarding supercapacitor performance under a plurality of conditions based on the historical data.

14. The method of claim 13, wherein generating the learning models is further based on data from one or more remote databases.

15. The method of claim 13, further comprising applying artificial intelligence to the historical data to identify one or more correlations between the supercapacitor performance and one or more of the conditions.

16. The method of claim 15, further comprising making predictions regarding future performance the at least one supercapacitor battery based on the identified correlations and the current state.

17. The method of claim 15, further comprising generating a display illustrating the correlations.

18. The method of claim 10, wherein identifying a current state of the at least one supercapacitor battery is based further on user input.

19. A non-transitory, computer-readable storage medium, having embodied thereon a program executable by a processor to perform a method for supercapacitor testing in electric vehicles, the method comprising:
storing in memory one or more thresholds for supercapacitor performance metrics and one or more recommended actions associated with different supercapacitor states;
disconnecting at least one electrochemical battery of an electric vehicle, wherein the at least one electrochemical provides power to the electric vehicle via a connection, and wherein disconnecting the at least one electrochemical battery includes interrupting the connection;
performing one or more tests on at least one supercapacitor battery of the electric vehicle, wherein results of the tests include one or more measurements each associated with a timestamp;
identifying a current state of the at least one supercapacitor battery based on a comparison of the test results to the thresholds; and
providing one of the recommended actions associated with the current state of the at least one supercapacitor battery to a designated recipient device.
